(19) United States
(12) Patent Application Publication
(10) Pub. No.: US 2021/0276003 A1
(43) Pub. Date: Sep. 9, 2021

(54) FLUID HANDLING DEVICE

(71) Applicant: Enplas Corporation, Kawaguchi-shi (JP)

(72) Inventors: Yasuhiro Watanabe, Saitama (JP); Seiichiro Suzuki, Saitama (JP)

(21) Appl. No.: 17/181,122

(22) Filed: Feb. 22, 2021

(30) Foreign Application Priority Data
Mar. 4, 2020 (JP) 2020-036705

(51) Int. Cl. B01L 3/00; B81B 1/00

(52) U.S. Cl. CPC B01L 3/00; B01L 2300/12; B81B 1/00

(57) ABSTRACT

A fluid handling device of the present invention includes a substrate and a film adhered to one surface of the substrate. The substrate includes a sample channel groove; a dispersion medium channel groove; a dispersion liquid generation recess for forming a dispersion liquid generation part which is connected to the sample channel and the dispersion medium channel, and in which the sample is to be divided by the dispersion medium to generate a dispersion liquid, and a dispersion liquid channel groove for forming a dispersion liquid channel which is connected to the dispersion liquid generation part, and which is for allowing the dispersion liquid to flow. The film contains an adhesive coated with a coating material in parts facing the sample channel groove, the dispersion medium channel groove, the dispersion liquid generation recess, and the dispersion liquid channel groove.

### CROSS REFERENCE TO RELATED APPLICATIONS

This application is entitled to and claims the benefit of Japanese Patent Application No. 2020-036705, filed on Mar. 4, 2020, the disclosure of which including the specification, drawings and abstract is incorporated herein by reference in its entirety.

### TECHNICAL FIELD

The present invention relates to a fluid handling device.

### BACKGROUND ART

In clinical, dietary, and environmental tests and the like, highly accurate analysis of cells, proteins, nucleic acids, and other trace amounts of analytes may be required. One of the methods for analyzing trace amounts of analytes generates minute droplets with a diameter of 0.1 to 1,000 μm from a liquid containing analytes to observe and analyze the droplets.

The droplets can be generated by allowing a dispersion medium (for example, oil) to flow so that the dispersion medium is repeatedly inserted into a flowing sample to divide the flowing sample. For example, Patent Literature (hereinafter, referred to as PTL) 1 discloses a method for generating droplets by discharging a dispersing phase into a continuous phase flowing in a microchannel, in a direction intersecting the continuous phase.

PTL 2 discloses a method for manufacturing a micro channel device as a method for manufacturing a device that generates such droplets. The method includes a bonding step for obtaining a joined body by bonding a resin substrate including a groove for a channel formed therein to a resin film disposed on the resin substrate so as to cover the surface, where the groove for a channel formed, of the resin substrate.

### CITATION LIST

### Patent Literature

PTL 1
WO 2002/068104
PTL 2
Japanese Patent Application Laid-Open No. 2012-206026

### SUMMARY OF INVENTION

### Technical Problem

A device (fluid handling device) which generates droplets is generally required to stably generate droplets. Conventional devices, such as the devices disclosed in PTLs 1 and 2, may not always stably generate droplets.

The present inventors have studied a case where droplets cannot be stably generated, and found that when a sample contains a solid component such as beads, or when the sample or a dispersion medium contains dust, the solid component or dust may clog a channel, causing a failure in the generation of droplets as desired in some cases.

The present inventors have further studied and found that the causes of clogging of the solid component or dust in the channel are as follows.

In the device for generating droplets as described above, a channel for allowing a sample to flow therein and a channel for allowing a dispersion medium to flow therein are formed from grooves formed in a substrate and a film disposed so as to cover the substrate. In such a device, an adhesive layer may be provided on the surface of the film on the substrate side for adhering the substrate and the film with the adhesive.

Bonding the substrate and the film in this way causes the adhesive to be exposed in the formed channel When a sample or dispersion medium containing a solid component or dust flows with the adhesive in an exposed state, the solid component or dust adheres to the adhesive and accumulates in the channel, which may cause the failure in generation of droplets.

The present invention has been made in view of the above circumstances. An object of the present invention is to provide a fluid handling device capable of stably generating droplets.

### Solution to Problem

The present invention provides the following fluid handling device:

A fluid handling device, comprising: a substrate and a film adhered to one surface of the substrate, wherein the substrate includes a sample channel groove for forming a sample channel along with the film, the sample channel being for allowing a sample to flow; a dispersion medium channel groove for forming a dispersion medium channel along with the film, the dispersion medium channel being for allowing a dispersion medium to flow; a dispersion liquid generation recess for forming a dispersion liquid generation part along with the film, the dispersion liquid generation part being connected to the sample channel and the dispersion medium channel, the dispersion liquid generation part being for generating a dispersion liquid containing a droplet of the sample dispersed in the dispersion medium by dividing the sample by the dispersion medium; and a dispersion liquid channel groove for forming a dispersion liquid channel along with the film, the dispersion liquid channel being connected to the dispersion liquid generation part, the dispersion liquid channel being for allowing the dispersion liquid to flow, and wherein the film contains an adhesive coated with a coating material in parts of the film, the parts facing the sample channel groove, the dispersion medium channel groove, the dispersion liquid generation recess, and the dispersion liquid channel groove.

### Advantageous Effects of Invention

The present invention provides a fluid handling device capable of stably generating droplets.

### BRIEF DESCRIPTION OF DRAWINGS

FIG. 1A is a plan view of a fluid handling device according to an embodiment of the present invention, and FIG. 1B is a cross-sectional view taken along line B-B shown in FIG. 1A;

FIG. 2 is a bottom view of a substrate of the fluid handling device shown in FIG. 1A;

FIG. 3 illustrates a mode with a film including a coated adhesive and an uncoated adhesive; and

FIG. 4 illustrates how droplets are generated in a dispersion liquid generation part.

### DESCRIPTION OF EMBODIMENTS

Hereinafter, an embodiment of the present invention will be described in detail with reference to the drawings. The dimensions or ratio of dimensions shown in the drawings may differ from the actual dimensions or ratio of dimensions for easy understanding of the descriptions.

(Fluid Handling Device)

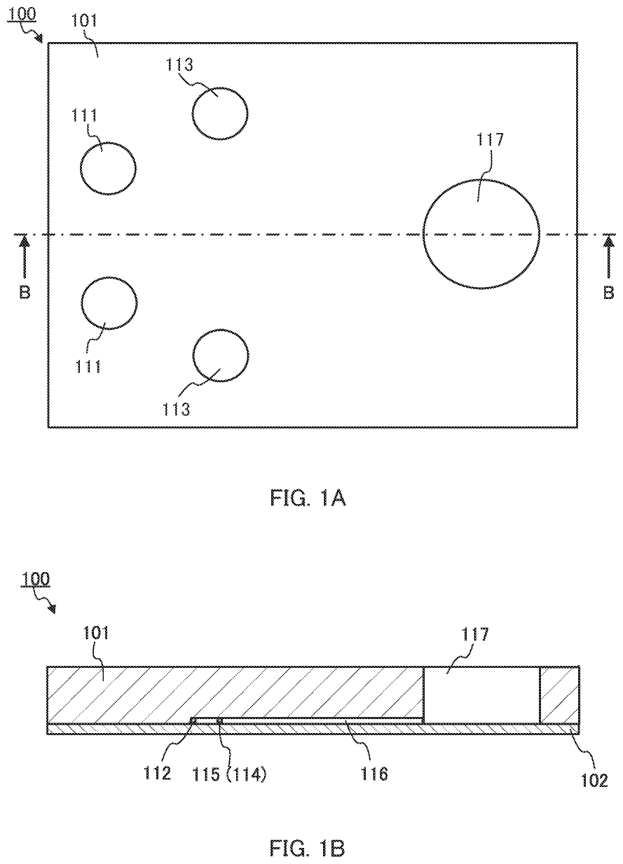

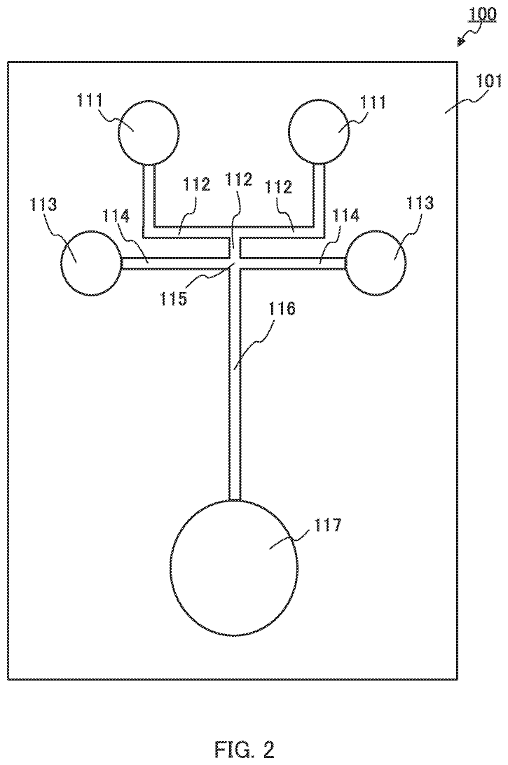

FIG. 1A shows a plan view of fluid handling device 100 according to an embodiment of the present invention, and FIG. 1B shows a cross-sectional view taken along line B-B shown in FIG. 1A. FIG. 2 shows a bottom view of substrate 101 of fluid handling device 100.

Fluid handling device 100 according to the embodiment of the present invention includes substrate 101 and film 102 disposed so as to cover one surface of substrate 101 as shown in FIG. 1B. Substrate 101 is a transparent substantially rectangular resin substrate. Substrate 101 may have any thickness, such as but not limited to, between 1 mm to 10 mm. Film 102 is a transparent substantially rectangular film made of resin. An adhesive layer is provided on one surface of film 102 (the surface to be joined to substrate 101). The adhesive layer will be described separately. The thickness of film 102 is, for example, 30 μm or more and 300 μm or less.

Substrate 101 and film 102 may be made of any material, which can be appropriately selected from known resins and glass. Examples of the materials for substrate 101 and film 102 include cycloolefin copolymers (COP), polypropylenes (PP), fluororesins (FEP), polytetrafluoroethylene resins (PTFE), polydimethylsiloxanes (PDMS), and elastomers. The elastomer may be a thermoplastic elastomer or a thermosetting elastomer. Examples of the thermosetting elastomer include polyurethane elastomers and polysilicone elastomers. Examples of the thermoplastic elastomer include styrene elastomers, olefin elastomers, and polyester elastomers. Specific examples of the olefin elastomers include polypropylene elastomers, whose examples include ZELAS manufactured by Mitsubishi Chemical Corporation (registered trademark of the company). Examples of the polyester elastomers include PELPRENE manufactured by TOYOBO CO., LTD (registered trademark of the company) and Hytrel manufactured by DU PONT-TORAY CO., LTD (registered trademark of the company). Each of substrate 101 and film 102 may contain only one type of material, or may contain two or more types of materials selected from the above.

As shown in FIGS. 1A to 2, substrate 101 includes sample introduction hole 111, sample channel groove 112, dispersion medium introduction hole 113, dispersion medium channel groove 114, dispersion liquid generation recess 115, dispersion liquid channel groove 116, and dispersion liquid collection hole 117. Sample introduction hole 111, dispersion medium introduction hole 113, and dispersion liquid collection hole 117 are optional components.

Hereinafter, each component will be described.

Sample introduction hole 111 is a through hole formed in substrate 101. Sample introduction hole 111 and film 102 disposed on substrate 101 so as to cover one opening of sample introduction hole 111 form a sample introduction part. That is, sample introduction hole 111 is a hole for forming, along with the film, the sample introduction part. The sample introduction part is an introduction port for introducing a sample into fluid handling device 100. Sample introduction hole 111 may have any structure which can form the sample introduction part for introducing a sample into a sample channel In the present embodiment, the shape of sample introduction hole 111 is a cylindrical. The number of sample introduction holes 111 may be appropriately selected according to the number of types of desired samples to be contained in a droplet. In the present embodiment, two sample introduction holes 111 are provided in substrate 101, but only one sample introduction hole 111 may be provided.

Sample channel groove 112 is a groove formed in substrate 101. Sample channel groove 112 and film 102 disposed so as to cover sample channel groove 112 form a sample channel That is, sample channel groove 112 is a groove for forming, along with film 102, the sample channel. The sample channel is connected to the sample introduction part and is a channel for allowing a sample introduced into the sample introduction part to flow therein. In the present embodiment, the upstream end of sample channel groove 112 is connected to sample introduction hole 111, and the downstream end of sample channel groove 112 is connected to dispersion liquid generation recess 115. The number of sample channel grooves 112 is not limited. Two sample channel grooves 112 are provided in the present embodiment, but only one sample channel groove 112 may be provided.

The cross sectional shape of sample channel groove 112 is not limited, which may be any shape such as a semicircular shape, a rectangular shape, or a circular shape. In addition, the size of the cross section of sample channel groove 112 is not limited. Herein, the “cross section of a channel groove” means a cross section in a direction orthogonal to the flow direction in the channel.

Dispersion medium introduction hole 113 is a through hole formed in substrate 101. Dispersion medium introduction hole 113 and film 102 disposed so as to cover one opening of dispersion medium introduction hole 113 form a dispersion medium introduction part. That is, dispersion medium introduction hole 113 is a hole for forming, along with film 102, the dispersion medium introduction part. The dispersion medium introduction part is an introduction port for introducing a dispersion medium (for example, oil) into fluid handling device 100. Dispersion medium introduction hole 113 may have any structure which can form the dispersion medium introduction part for introducing a dispersion medium into a dispersion medium channel. In the present embodiment, the shape of dispersion medium introduction hole 113 is a cylindrical. Two dispersion medium introduction holes 113 are provided in substrate 101 in the present embodiment. The number of dispersion medium introduction holes 113 is two in the present embodiment, but the number may be one.

Dispersion medium channel groove 114 is a groove formed in substrate 101. Dispersion medium channel groove 114 and film 102 disposed so as to cover dispersion medium channel groove 114 form a dispersion medium channel. That is, dispersion medium channel groove 114 is a groove for forming, along with film 102, the dispersion medium channel. The dispersion medium channel is connected to the dispersion medium introduction part and is a channel for allowing a dispersion medium introduced into the dispersion medium introduction part to flow therein. In the present embodiment, dispersion medium channel groove 114 is a channel groove extending in the short-side direction of fluid handling device 100. The upstream end of dispersion medium channel groove 114 is connected to dispersion medium introduction hole 113, and the downstream end of dispersion medium channel groove 114 is connected to dispersion liquid generation recess 115.

The cross sectional shape of dispersion medium channel groove 114 is not limited, which may be any shape such as a semicircular shape, a rectangular shape, or a circular shape. In addition, the size of the cross section of dispersion medium channel groove 114 is not limited.

In the above description, substrate 101 of fluid handling device 100 includes two dispersion medium introduction holes 113 and two dispersion medium channel grooves 114, but each number of dispersion medium introduction holes 113 and dispersion medium channel grooves 114 is not limited, and may be, for example, one.

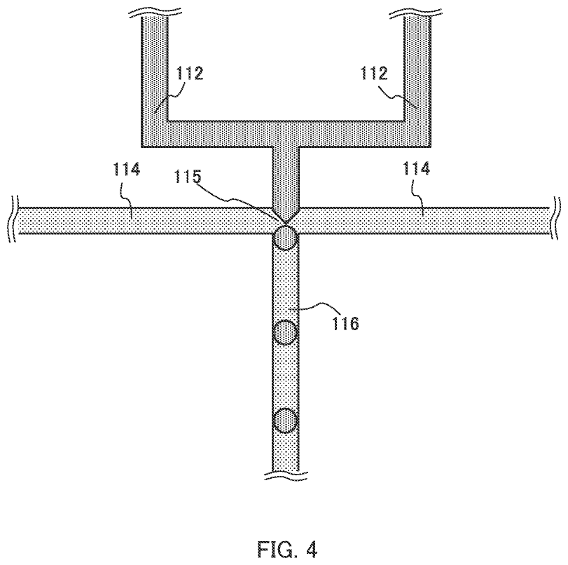

Dispersion liquid generation recess 115 is a recess formed in substrate 101. Dispersion liquid generation recess 115 and film 102 disposed so as to cover dispersion liquid generation recess 115 form a dispersion liquid generation part. That is, dispersion liquid generation recess 115 is a recess for forming, along with film 102, the dispersion liquid generation part. Dispersion liquid generation recess 115 is connected to sample channel groove 112 and dispersion medium channel groove 114. In dispersion liquid generation recess 115, a sample flowing through sample channel groove 112 is divided by a dispersion medium flowing through dispersion medium channel groove 114, thereby generating a dispersion liquid containing droplets of the sample dispersed in the dispersion medium. Dispersion medium channel groove 114 is connected to sample channel groove 112 to form dispersion liquid generation recess 115. In the present embodiment, dispersion medium channel grooves 114 are connected to sample channel groove 112 from the left and right sides of sample channel groove 112, and the sample flowing through sample channel groove 112 is divided by the dispersion medium flowing from both the left and right sides, thereby generating droplets of the sample (see FIG. 4).

The size of dispersion liquid generation recess 115 affects the size of the droplet, and in general the diameter of the droplet is approximately the same as the opening of sample channel groove 112. The size (depth and width) of the opening of sample channel groove 112 is thus appropriately selected according to the desired diameter of the droplet.

Dispersion liquid channel groove 116 is a groove formed in substrate 101. Dispersion liquid channel groove 116 and film 102 disposed so as to cover dispersion liquid channel groove 116 form a dispersion liquid channel. That is, dispersion liquid channel groove 116 is a groove for forming, along with film 102, the dispersion liquid channel The dispersion liquid channel is connected to the dispersion liquid generation part and is a channel for allowing the generated dispersion liquid to flow therein. The upstream end of dispersion liquid channel groove 116 is connected to dispersion liquid generation recess 115, and the downstream end of dispersion liquid channel groove 116 is connected to dispersion liquid collection hole 117.

The cross sectional shape of dispersion liquid channel groove 116 is not limited, which may be any shape such as a semicircular shape, a rectangular shape, or a circular shape. The size (depth and width) of the cross section of dispersion liquid channel groove 116 is not limited as long as the movement of droplets is not restricted.

Dispersion liquid collection hole 117 is a through hole formed in substrate 101. Dispersion liquid collection hole 117 and film 102 disposed so as to cover one opening of dispersion liquid collection hole 117 form a dispersion liquid collection part. That is, dispersion liquid collection hole 117 is a hole for forming, along with film 102, the dispersion liquid collection part. The dispersion liquid collection part is an outlet port for collecting a dispersion liquid containing droplets. Dispersion liquid collection hole 117 may have any structure which can form the dispersion liquid collection part for collecting a dispersion liquid. In the present embodiment, the shape of dispersion liquid collection hole 117 is a cylindrical. The size of dispersion liquid collection hole 117 may be appropriately set according to the amount of the dispersion liquid to be collected.

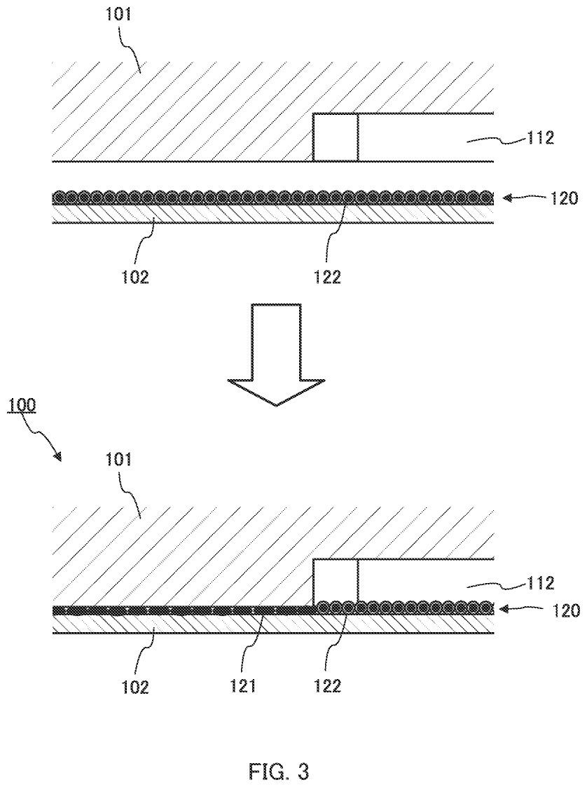

In the following, adhesive layer 120 of film 102 will be described (see FIG. 3). As described above, fluid handling device 100 according to the present embodiment includes substrate 101 and film 102 disposed so as to cover one surface of substrate 101 (see FIG. 1B). Film 102 is adhered to substrate 101 with an adhesive.

In film 102 before being adhered to substrate 101, adhesive layer 120 is provided on one surface of film 102 (the surface to be joined to substrate 101). The adhesive in adhesive layer 120 is coated with a coating material. For example, the adhesive is encapsulated in a capsule as a coating material, and adhesive layer 120 contains a large number of capsules in which the adhesive is encapsulated. As the adhesive is coated with the coating material in this way, no sticky feeling can be found upon touching adhesive layer 120 of film 102.

Film 102 containing adhesive layer 120 having such a feature is superposed on the surface, with grooves to become channels formed therein, of substrate 101 in such a way that adhesive layer 120 is in contact with the surface. Pressure is then applied to film 102 to adhere film 102 to substrate 101. In a region where substrate 101 and adhesive layer 120 are in direct contact with each other, the coating material in adhesive layer 120 is destroyed by the applied pressure to expose the adhesive, and exposed adhesive 121 causes substrate 101 and film 102 to adhere with each other as shown in FIG. 3. On the other hand, in a region where substrate 101 and adhesive layer 120 are not in contact with each other (for example, a region where a through hole or a groove is formed, such as sample channel groove 112, in substrate 101), the pressure applied to film 102 is released, and thus the coating material in adhesive layer 120 is not destroyed and the adhesive is not exposed. In fluid handling device 100 according to the present embodiment, film 102 still contains adhesive 122 which is coated with the coating material in the region covering the through hole or groove of substrate 101. That is, in parts facing sample channel groove 112, dispersion medium channel groove 114, dispersion liquid generation recess 115, and dispersion liquid channel groove 116, film 102 contains the adhesive coated with the coating material. In the parts covering these channel grooves and through holes, the adhesive in adhesive layer 120 is coated, thus the adhesive is not exposed in the channel or the like, and a foreign matter (dust) in a liquid or a solid in a sample is less likely to adhere to and be accumulated in the channel or the like.

Examples of the above-described adhesive include acrylic adhesives, silicone adhesives, urethane adhesives, and epoxy adhesives.

Examples of a material constituting the above coating material include various polymers such as epoxy resin cured products, polystyrene, polymethacrylic acid methyl ester, ethylene-vinyl acetate copolymer, polyvinyltoluene, and acrylic rubber, polymers obtained by using an ethylene-based monomer such as vinylidene chloride, acrylonitrile, or methacrylic acid as a main component monomer, engineering plastics such as polysulfone and polyetherimide, polyurea, polyurethane, amino resin, and acrylic resin.

Examples of the above described film, in which formed is adhesive layer 120 containing an adhesive coated with a coating material that exposes the adhesive in response to pressure, include Thermal Seal RTS Sealing Films manufactured by EXCEL Scientific, Inc. (a polyolefin film with a film thickness of 50 μm provided with adhesive layer 120 containing a large number of capsules where an average particle size of the capsule is 50 μm and a silicone adhesive is encapsulated in the capsule).

(Fluid Handling Method)

In the following, a method for generating and collecting droplets of a sample by using fluid handling device 100 according to the present embodiment (fluid handling method) will be described.

A sample is introduced into a sample introduction part (sample introduction hole 111), and a dispersion medium (for example, oil) is introduced into two dispersion medium introduction parts (dispersion medium introduction holes 113).

The sample is, for example, a liquid to be sorted as a droplet, or a liquid containing an object to be sorted by being encapsulated in the droplet. Examples of the sample include liquids individually containing cells, proteins, or nucleic acids. The sample may contain a solid such as beads on which nucleic acid or the like is immobilized. Specifically, for example, cells (intracellular substance) are placed in one sample introduction part (sample introduction hole 111), and a solid such as beads, which are to be encapsulated in droplets together with the cells (intracellular substance) and to which substances to act on the cells (intracellular substance) are bound, is placed in the other sample introduction part.

Since an adhesive is not exposed in a channel or the like in fluid handling device 100 according to the embodiment of the present invention, a solid which may be contained in a sample is less likely to adhere to and be accumulated in the channel or the like. Fluid handling device 100 according to the embodiment of the present invention is thus particularly advantageous when the sample channel of the device allows a sample containing a solid to flow therethrough. Similarly, a solid such as dust which may be contained in a liquid (sample and/or dispersion medium) is less likely to be accumulated.

The above described dispersion medium may be any medium, which has low compatibility with the sample and can divide the sample flowing through the sample channel (sample channel groove 112) in the dispersion liquid generation part (dispersion liquid generation recess 115).

The sample is allowed to flow through the sample channel (sample channel groove 112) by being pressurized in the sample introduction part (sample introduction hole 111), and the dispersion medium is allowed to flow through the dispersion medium channel (dispersion medium channel groove 114) by being pressurized in the dispersion medium introduction part (dispersion medium introduction hole 113). Alternatively, the sample and dispersion medium may be introduced into the corresponding sample channel (sample channel groove 112) and dispersion medium channel (dispersion medium channel groove 114) by being decompressed in the dispersion liquid collection part (dispersion liquid collection hole 117).

As shown in FIG. 4, the sample flowing from two sample channels (sample channel grooves 112) is divided by the dispersion medium flowing through two dispersion medium channels (dispersion medium channel grooves 114) at the dispersion liquid generation part (dispersion liquid generation recess 115). The sample thus becomes droplets whose peripheries are surrounded by the dispersion medium, and a dispersion liquid containing droplets of the sample dispersed in the dispersion medium is generated.

The dispersion liquid containing the droplets flows through the dispersion liquid channel (dispersion liquid channel groove 116) and reaches the dispersion liquid collection part (dispersion liquid collection hole 117).

(Effects)

An adhesive is not exposed in a channel or a recess in fluid handling device 100 according to the embodiment of the present invention. A solid which may be contained in a sample or a foreign matter such as dust which may be contained in a liquid is thus less likely to adhere to and be accumulated in a channel. Accordingly, fluid handling device 100 according to the embodiment of the present invention can stably generate droplets.

### INDUSTRIAL APPLICABILITY

The fluid handling device and fluid handling method of the present invention can be applied, for example, to clinical tests, food tests, and environmental tests.

### REFERENCE SIGNS LIST

100 Fluid handling device
101 Substrate
102 Film
111 Sample introduction hole
112 Sample channel groove
113 Dispersion medium introduction hole
114 Dispersion medium channel groove
115 Dispersion liquid generation recess
116 Dispersion liquid channel groove
117 Dispersion liquid collection hole
120 Adhesive layer
121 Exposed adhesive
122 Coated adhesive

What is claimed is:

1. A fluid handling device, comprising:
a substrate and a film adhered to one surface of the substrate, wherein the substrate includes
a sample channel groove for forming a sample channel along with the film, the sample channel being for allowing a sample to flow,
a dispersion medium channel groove for forming a dispersion medium channel along with the film, the dispersion medium channel being for allowing a dispersion medium to flow,
a dispersion liquid generation recess for forming a dispersion liquid generation part along with the film, the dispersion liquid generation part being connected to the sample channel and the dispersion medium channel, the dispersion liquid generation part being for generating a dispersion liquid containing a droplet of the sample dispersed in the dispersion medium by dividing the sample by the dispersion medium, and
a dispersion liquid channel groove for forming a dispersion liquid channel along with the film, the dispersion liquid channel being connected to the dispersion liquid generation part, the dispersion liquid channel being for allowing the dispersion liquid to flow, and wherein
the film contains an adhesive coated with a coating material in parts of the film, the parts facing the sample channel groove, the dispersion medium channel groove, the dispersion liquid generation recess, and the dispersion liquid channel groove.

2. The fluid handling device according to claim 1, wherein the film is adhered to the one surface of the substrate by the adhesive.

3. The fluid handling device according to claim 1, wherein the adhesive coated with the coating material is an encapsulated adhesive in a capsule.

4. The fluid handling device according to claim 1, wherein the adhesive coated with the coating material is exposed by the coating material being destroyed by pressure.

5. The fluid handling device according to claim 1, wherein the sample channel is for allowing a sample containing a solid to flow.
